(19) United States
(12) Patent Application Publication
(10) Pub. No.: US 2020/0017970 A1
(43) Pub. Date: Jan. 16, 2020

(54) WATER-INSENSITIVE METHODS OF FORMING METAL OXIDE FILMS AND PRODUCTS RELATED THERETO

(71) Applicant: LOTUS APPLIED TECHNOLOGY, LLC, Hillsboro, OR (US)

(72) Inventor: Eric R. Dickey, Portland, OR (US)

(21) Appl. No.: 16/510,112

(22) Filed: Jul. 12, 2019

Related U.S. Application Data
(60) Provisional application No. 62/697,116, filed on Jul. 12, 2018.

(51) Int. Cl. C23C 16/455

(52) U.S. Cl. CPC C23C 16/45553; C23C 2222/20; C23C 16/45538

(57) ABSTRACT

Water-insensitive methods for forming metal oxide films disclosed herein can be used to form coated substrates. The methods can be used with moisture-laden substrates. Moisture-sensitive films can be deposited on the metal oxide films.

### CROSS-REFERENCE TO RELATED APPLICATIONS

Under 35 U.S.C. § 119(e), this application claims the benefit of U.S. Provisional Patent Application No. 62/697,116, entitled “WATER-INSENSITIVE METHODS OF FORMING METAL OXIDE FILMS AND PRODUCTS RELATED THERETO,” filed Jul. 12, 2018, the contents of which are hereby incorporated herein by reference in their entirety.

### TECHNICAL FIELD

The present disclosure relates to metal oxide films and particularly to water-insensitive methods for forming such films and products related to such films.

### BACKGROUND

Atomic layer deposition (ALD) is similar to conventional chemical vapor deposition (CVD) processes but distinct in its self-limiting growth at the surface of the substrate on an atomic level. ALD is a process that generates thin films that are extremely conformal, highly dense, and provide pinhole-free coverage. A complete ALD cycle is often referred to as a combination of two half-reactions. A single ALD cycle generally includes four steps: (1) substrate exposure to gaseous precursor molecules that react with the substrate surface or other existing molecules on the surface (“reactive sites”)—this is the first half-reaction; (2) purge any precursor molecules not chemically bonded to the surface; (3) introduce gaseous reactant molecules that react with precursor molecules and form the desired molecule on the surface—this is the second half-reaction; and (4) purge any reactant molecules that were not reacted and also purge any byproducts of reaction, leaving only the desired molecules on the surface, such as a metal oxide.

Water is a common reactant molecule used in step three for accomplishing the second half-reaction. For example, trimethylaluminum (TMA) is highly reactive with water and readily forms aluminum oxide on contact with water. Thus, TMA molecules can be chemisorbed to reactive sites during step one. Water can be introduced during step three and aluminum oxide formed at the reactive sites. However, if molecular water is present when a substrate is exposed to TMA, then CVD aluminum oxide growth will occur, instead of self-limited, sequential ALD growth.

Substrates are typically degassed and/or dried prior to ALD to avoid off-gassing of water during ALD and the resultant unwanted reactions. When water is produced during the second half-reaction or is used as the reactant molecule, the step four purge is typically selected for a long enough time period to remove the non-chemisorbed water from the surface of the substrate. For low temperature processes, such as below 300° C., desorbing all of the water from the surface of the substrate can take a significant amount of time. Drying and degassing substrates and lengthy purge times increase the expense and reduce the productivity of conventional ALD metal oxide formation processes.

A need remains for water-insensitive ALD processes that could be used to grow metal oxides in the presence of water.

### BRIEF DESCRIPTION OF THE DRAWINGS

FIG. 1 illustrates one embodiment of a coated substrate disclosed herein.

FIG. 2 illustrates a cross-section of the rotary spatial ALD reactor used in certain experiments.

FIG. 3 illustrates a cross-section of the same reactor illustrated in FIG. 2, but with water vapor intentionally introduced into the reactor for certain experiments.

### DETAILED DESCRIPTION

The present disclosure relates to metal oxide films and particularly to water-insensitive methods for forming such films and products related to such films.

In some embodiments of water-insensitive methods of forming a metal oxide on a substrate, the methods comprise introducing a substrate into an atomic layer deposition (ALD) reactor and performing multiple ALD cycles to grow a metal oxide on the substrate. The methods include exposing the substrate, while in the ALD reactor, to a gaseous amino-based metal precursor in the presence of trimethylaluminum (TMA) detectable water (i.e., to chemisorb the amino-based metal precursor to reactive sites to achieve the first half-reaction). The amino-based metal precursor does not include alkoxy groups directly bonded to the metal. The methods further include subsequently exposing the substrate to an oxidant and forming the metal oxide on the substrate (i.e., second half-reaction). The preceding steps are repeated to grow the metal oxide film on the substrate. Importantly, a growth rate of the metal oxide film indicates a lack of reaction between the amino-based metal precursor and the water. Thus, the metal oxide film can be grown using self-limiting, sequential ALD reactions, in the presence of water.

There are a number of advantages to being able to grow metal oxide films with water present during exposure to the amino-based metal precursor. For example, moisture-laden substrates can be coated with a metal oxide without the need for degassing or drying the substrates. Moisture-sensitive films can then be deposited on the metal oxides. In another example of advantages, since water can be present during the amino-based metal precursor exposure, purge times can be reduced, since it may be unnecessary to desorb all of the physisorbed water present on the surface of the substrate. Additionally, water vapor can be intentionally introduced during the gaseous amino-based metal precursor exposure. Intentional water introduction can be used, for example, to modify substrate surface characteristics (such as to increase the number of hydroxyl groups present on the substrate surface), without concern of reactivity with the amino-based metal precursor.

As mentioned above, the amino-based metal precursor does not include alkoxy groups directly bonded to the metal. Additionally, in certain embodiments, the amino-based metal precursor does not include halo or haloalkyl groups directly bonded to the metal. In certain embodiments, the amino-based metal precursor does not contain any alkoxy groups, halo groups, or haloalkyl groups.

As used herein, “alkoxy” refers to —O-alkyl with the oxygen atom as the point of attachment to the remainder of the molecule.

“Halo” refers to chloro, fluoro, bromo, or iodo substituents.

Likewise, “haloalkyl” refers to an alkyl group that is substituted with one or more fluorine, chlorine, bromine or iodine atoms, e.g., fluoromethyl, difluoromethyl, trifluoromethyl, pentafluoroethyl, 1,1-difluoroethyl, chloromethyl, chlorofluoromethyl and trichloromethyl groups.

The term “alkyl” as used herein by itself or as part of another group refers to a hydrocarbon, saturated or unsaturated, straight chain or branched chain group with a carbon atom as the point of attachment to the remainder of the molecule. An alkyl group may be in unsubstituted form or substituted form with one or more substituents, in addition to a named part of another group (e.g., in addition to a halo substituent). Example alkyl groups include methyl, ethyl, propyl, isopropyl, butyl, sec-butyl, tert-butyl, 3-pentyl, hexyl, ethenyl, 1-propenyl, 2-propenyl, 2-methyl-1-propenyl, 1-butenyl, 2-butenyl, ethynyl, 1-propynyl, 1-methyl-2-propynyl, 2-propynyl, 1-butynyl and 2-butynyl, each of which may be optionally substituted with one or more substituents.

As used herein, “amino” refers to an —NR^{x}R^{y} group, with the nitrogen atom as the point of attachment to the remainder of the molecule. In certain embodiments, R^{x} and R^{y} are not particularly limited. For example, R^{x} and R^{y} can independently be hydro, any organic substituent, another metal atom (e.g., another silicon atom), or bonded together to form a ring structure. Additionally, all of the foregoing examples of R^{x} and R^{y} can be further substituted. That said, in particular embodiments, R^{x} and R^{y} are independently either hydro or alkyl (including unsubstituted alkyl and saturated unsubstituted alkyl), such as in particular embodiments of when the nitrogen of the amino group is directly bonded to a silicon atom.

It should be understood that the metal of the amino-based metal precursor will determine the type of metal oxide formed. In certain embodiments, the amino-based metal precursor includes an amino-based silicon precursor and the resulting metal oxide film comprises a silica film. In particular, the amino-based silicon precursor may comprise at least one nitrogen atom (i.e., an amino nitrogen) directly bonded to a silicon atom. Additionally, the silicon atom may further be directly bonded to only atoms independently selected from other nitrogen atoms (e.g., additional amino groups), other silicon atoms, or hydrogen atoms. Even more particularly, the silicon atom may further be directly bonded to only atoms independently selected from other nitrogen atoms or other silicon atoms.

Examples of amino-based silicon precursors include, but are not limited to, SAM-24 (Air Liquide), also known as bisdiethylaminosilane (BDEAS), ORTHRUS (Air Liquide), trisdiethylaminosilane (TDMAS or 3DMAS), bistertbutylaminosilane (BTBAS), diisopropylaminosilane (DIPAS), and bisdiisoproplyaminodislane (BDIPADS)—dimer version of DIPAS. Other examples of amino-based silicon precursors include, but are not limited to, trisilylamine (TSA), neopentasilane, N(SiH₃)₃, and tris(isopropylamino)silane (TIPAS).

Amino-based metal precursors, including amino-based silicon precursors, can be reactive with water. For example, BDEAS is known to readily react with liquid water to produce diethylamine. It has been discovered that moisture-reactive amino-based metal compounds, such as moisture-reactive amino-based silicon compounds, when in gaseous form, can be used as ALD precursors in the presence of water vapor without reacting with the water. Without wishing to be bound by theory, it is believed that moisture-reactive amino-based metal precursors, when in gaseous form and at low pressure and temperature, will not readily react with water vapor present in the ALD reactor. This may be particularly true for moisture-reactive amino-based metal precursors where the nitrogen of the amino group is directly bonded to a silicon atom. Accordingly, in some embodiments, the reactor chamber pressure may be maintained at less than 50 Torr, such as, by way of non-limiting example, 4 mTorr to 40 Torr.

“TMA detectable water” as used herein, refers to a quantity of water sufficient to form a detectable aluminum oxide film, if TMA were present. Thus, the term does not refer to a specific quantity of water, but does require at least a minimum amount of water to result in an aluminum oxide film, if the water was reacted with TMA. “TMA detectable water” can be determined by introducing a sample of the substrate into the ALD reactor and exposing the substrate to TMA, instead of the amino-based metal precursor. If an aluminum oxide film forms on the sample substrate or on any of the reactor surfaces, then TMA detectable water is present. If a film does not form, then TMA detectable water is not present. An aluminum oxide film can be detected a number of ways, such as by observing visible growth of an aluminum oxide film on the interior surfaces of the reactor. Quantitative approaches include using ellipsometry or optical interference measurements on a smooth substrate to detect the presence and amount of an aluminum oxide film. Chemical analyses, such as utilizing RBS, are also possible detection methods. Furthermore, “TMA detectable water” distinguishes from reactor conditions where water is not present or is present in amounts that would be tolerable for an ALD process utilizing TMA.

The embodiments disclosed herein can be used in the absence of water, but one of the benefits of the methods disclosed herein is that the gaseous amino-based metal precursor exposure can be performed in the presence of water. Thus, the embodiments disclosed herein can be used with moisture-laden substrates. For example, a substrate containing significant quantities of water can be coated (such as an ungassed or partially degassed substrate), even though the substrate may be off-gassing TMA detectable amounts of water during the ALD process. Examples of significant quantities of water in a moisture-laden substrate include, but are not limited to, a water content of at least 0.001% by volume or at least 0.01% by volume of the bulk structure of the substrate, in components in or on the bulk structure of the substrate, or both. “Moisture-laden substrate,” as the term is used herein, does not include a substrate with liquid water present. Thus, in some embodiments, a moisture-laden substrate may have at most 5% water by volume (e.g., 0.001% to 5%, 0.01% to 5%, 0.1% to 5%, or 0.1% to 3%).

Many types of moisture-laden substrates could benefit from the methods disclosed herein. For example, printed circuit boards (PCBs) often have temperature-sensitive components in or on the bulk structure of the PCBs. Prior to encapsulating the PCBs, such as with parylene, it is commonly necessary to degas the PCBs to remove water present in the bulk structure and in any of the components. At the low temperatures (e.g., 50°-100° C.) required to avoid damaging the components, degassing can take a very long time. Alternatively, using the methods disclosed herein, it may not be necessary to degas the PCBs prior to encapsulation. A thin film of a metal oxide, such as silicon dioxide, can be grown on the PCBs and effectively seal moisture within the PCBs.

In another example, the methods disclosed herein could be used for forming optical coating on polymer lenses. A thin film of a metal oxide, such as silicon dioxide, can be grown on the polymer lenses and effectively seal moisture within the polymer lenses. Moisture-sensitive films, with desired optical properties, could then be deposited on the polymer lenses.

In yet another example, porous membranes can be difficult to degas, but it may be desirable to deposit moisture-sensitive films, such as metal oxides, on the porous membranes. For example, it may be desirable to deposit metal oxides on porous polymer membranes for battery separators. Such membranes can, for example, be microporous and have a bulk structure thickness of up to one millimeter, such as 8 microns to 50 microns. Such porous polymer membranes are typically produced in a continuous roll-to-roll process. Furthermore, the polymer may be temperature-sensitive. The amount of time and space required to degas such porous polymer membranes can be significant. Utilizing the methods disclosed herein, metal oxide films, such as silicon dioxide, can be formed on the porous polymer membranes without a need for degassing or drying the membranes, saving significant expense, reducing overall process time, and increasing production throughput of the substrates.

The TMA detectable water present during exposing the substrate to the gaseous amino-based metal precursor may include residual water present in the ALD reactor, such as from a prior process step. Thus, the substrate may be dry or moisture-laden, but residual water is present in the ALD reactor. For example, during step three of the ALD cycle (i.e., during the second half-reaction) water may be an oxidant or may be produced by the second half-reaction. The purge time of step four of the ALD cycle can be shortened to a sufficient amount of time to remove non-water products proximal to or on the substrate; however, the purge time can be selected so as to be insufficient to desorb physisorbed water from the substrate below TMA-detectable levels. This can be particularly beneficial for low temperature ALD processes (temperatures below 300° C.) where the time required to desorb physisorbed water becomes significant. For example, the time to remove water exponentially increases as the temperature decreases below 100° C. Thus, using the methods disclosed herein, at low temperatures, short purge times can still be used, increasing productivity and throughput.

The residual water may also be present from exposure of the reactor internals to ambient air. For example, water vapor can be present for a time after the internal parts of the reactor are exposed to ambient room air during a vent and/or exchange of substrates. In such situations, air containing water in trapped internal volumes may only slowly be pumped out, keeping residual water vapor in the reactor for a time. Additionally, after exposure to ambient air, water physisorbed on internal surfaces of the reactor may slowly come off of the surfaces. This is especially true for low reactor temperatures. For water-sensitive processes, such as TMA-based Al₂O₃ deposition, this means that an extended pumping time and/or preheating is needed, after reaching the necessary process pressure, before starting the run. This extended pumping/heating time is not needed for the methods disclosed herein using amino-based metal precursors, such as amino-based silicon precursors.

The TMA detectable water present during exposing the substrate to the gaseous amino-based metal precursor can include water vapor intentionally introduced during the gaseous amino-based metal precursor exposure. As discussed previously, intentional water introduction can be used, for example, to modify substrate surface characteristics, without concern of reactivity with the gaseous amino-based metal precursor.

Whether the water vapor is present from off-gassing, residual from a prior process step or ambient air, or intentionally introduced, non-limiting examples of TMA detectable water present include water vapor with a partial pressure of at least 10⁻⁵ Torr or at least 10⁻³ Torr.

Subsequently exposing the substrate to the oxidant (i.e., step three of the ALD cycle and the second half-reaction) can include exposing the substrate to an oxygen-containing plasma. The oxygen-containing plasma includes an activated oxygen species.

As should be understood, oxygen atoms included in the metal oxide are provided by reaction of the oxidant (e.g., activated oxygen species). That is, the oxidant supplied to the surface of the substrate reacts with chemisorbed metal species (e.g., silicon species).

The oxidant may be a mixture or may consist primarily of a single compound. In some embodiments, an oxidant is selected that has a deactivated form to which the metal precursors are insensitive, so that co-mingling of the deactivated oxidant with another precursor will not result in adventitious film and/or particle formation. Put differently, the oxidant source may be selected so that the oxidant (e.g., activated oxygen species) is reactive with the chemisorbed metal while the oxidant source is not, as described in U.S. Pat. No. 8,187,679, the contents of which are incorporated herein by reference.

In some embodiments, the oxidant may include oxygen radicals generated by plasma activation of the oxidant source. For example, a plasma supplied with an oxygen-containing gas consisting primarily of dry air (including dry air synthesized from a blend of nitrogen and oxygen gases) may generate oxygen radicals. Other non-limiting examples of gaseous oxidant sources include one or more of carbon monoxide (CO), carbon dioxide (CO₂), nitrogen monoxide (NO), and nitrogen dioxide (NO₂), and mixtures of nitrogen (N₂) and carbon dioxide. In some embodiments, an oxygen-containing plasma may directly contact the substrate (e.g., a direct plasma). Indirect (e.g., remote plasma) activation and transport of oxygen radicals to the substrate surface may be employed in some embodiments.

Other radical activation energy sources and plasma ignition/stabilization gases may also be employed as the oxidant without departing from the scope of the present disclosure. In some embodiments, activated oxygen species including ozone (O₃) may be generated, remotely or proximal to the substrate, from an oxidant source. In some embodiments, activated oxygen species may be generated by thermally decomposing or cracking an oxidant source. Hydrogen peroxide (H₂O₂) is a non-limiting example of an oxidant source that may be used in a thermally activated ALD process. Oxygen radicals generated from hydrogen peroxide may react with chemisorbed metal species to form a metal oxide. In some of such embodiments, H₂O₂ may be blended with water (H₂O) as water vapor to alter the concentration of oxygen radicals by shifting the kinetic equilibrium of the radical formation process.

When the oxidant is an oxygen-containing plasma, it may be possible to perform the methods disclosed herein at low temperatures (e.g., less than 300° C.). This can be beneficial for temperature-sensitive substrates. The methods disclosed herein may include maintaining the ALD reactor at a temperature of less than 300° C., including less than 200° C., less 150° C., less than 100° C., or less than 50° C. As discussed previously, at temperatures below 100° C. it becomes difficult to remove water sorbed to the surface of the substrate. However, as discussed previously, residual water is not problematic for the methods disclosed herein. Therefore, temperature-sensitive substrates can be coated with metal oxides at low temperatures and in the presence of residual water.

The ALD reactors used to perform the methods disclosed herein can be pulse reactors or spatial ALD reactors. U.S. Pat. Nos. 8,187,679, 8,202,366, and 9,297,076, the contents of each of which are incorporated herein by reference, disclose embodiments of spatial ALD reactors that could be used in the methods disclosed herein. U.S. Pat. No. 4,058,430, the contents of which are incorporated herein by reference, discloses embodiments of pulse reactors that could be used in the methods disclosed herein.

The ability to grow a metal oxide, such as silicon dioxide, on a moisture-laden substrate can be beneficial when it is desirable to deposit a moisture-sensitive film on the moisture-laden substrate. A moisture-laden substrate can be coated with the metal oxide and then the moisture-sensitive film formed on the metal oxide. As used herein, a “moisture-sensitive film” refers to a film that is water reactive after it is produced or will undergo an undesirable change in properties in the presence of water. A “moisture-sensitive film” also refers to a film that results from materials used to form the film where the materials are water reactive under the conditions employed to form the film. Or stated another way, the resultant film is considered water-sensitive even if the final form of the film is not water-sensitive, but the method used to form the film is water-sensitive.

In some embodiments, methods of forming a moisture-sensitive film on a moisture-laden substrate include providing a moisture-laden substrate, growing a metal oxide film on the moisture-laden substrate utilizing atomic layer deposition (ALD) with an amino-based metal precursor devoid of alkoxy groups (and optionally halo or haloalkyl groups) directly bonded to the metal or optionally not even present in the molecule, and then depositing a moisture-sensitive film on the moisture-laden substrate. The methods disclosed herein for growing the metal oxide can be used. Depositing the moisture-sensitive film can include growing the moisture-sensitive film utilizing ALD or CVD, lamination, brushing, dip coating, sputtering, or combinations thereof. One of skill in the art, with the benefit of this disclosure, would understand that there are a variety of methods known in the art for depositing films that may be moisture-sensitive.

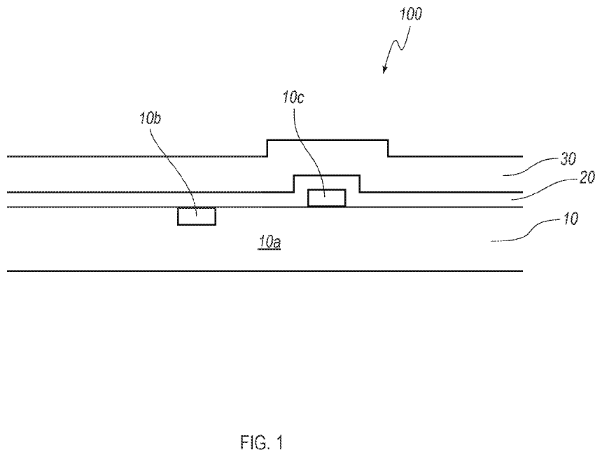

Coated substrates made by the methods disclosed herein are also contemplated by this disclosure. For example, FIG. 1 illustrates an exemplary embodiment of a coated substrate 100. The coated substrate 100 includes a moisture-laden substrate 10. The bulk structure 10a of the moisture-laden substrate 10 includes a component 10b located in the bulk structure 10a and an additional component 10c located on the bulk structure 10a. A metal oxide film 20 grown on the upper surface of the moisture-laden substrate 10 conforms to the topology of the upper surface of the moisture-laden substrate 10. A moisture-sensitive film 30 is deposited on the metal oxide film 20. In the illustrated embodiment, the moisture-sensitive film 30 conforms to the topology of the metal oxide film 20. However, it should be understood that depending on the deposition method used for the moisture-sensitive film 30, the film may or may not conform to the metal oxide film 20.

### Example—ALD of SiO₂ Using an Aminosilane in the Presence of Water

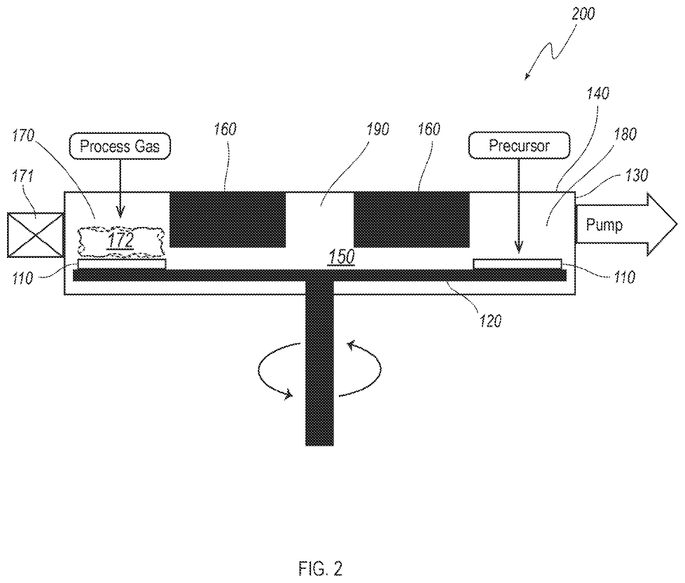

FIG. 2 illustrates a cross-section of the rotary spatial ALD reactor 200 used in the experiments. The reactor 200 includes a heated platen 120, sidewalls 130, and heated lid 140 that defined a chamber 150. Substrates 110 were located circumferentially on the upper surface of the heated platen 120. The reactor 200 was a “warm wall” reactor in that the temperature of the substrates 110 was higher than the temperature of the sidewalls 130. Barriers 160 separated a plasma region 170 from a precursor region 180. A direct plasma 172 was produced by a plasma generator 171. The substrates 110 were rotated via rotation of the heated platen 120 to provide sequential exposure to an amino-based metal precursor and plasma 172. The number of rotations defined the number of ALD cycles. In the configuration used for this study, the process gas was introduced into the plasma region 170 of the chamber 150. Pumping was applied only to the precursor region 180. This ensured that all of the process gases and background vapors present in the chamber 150 pass through the precursor region 180 prior to exiting the reactor 200.

In the first two cases, no water vapor was deliberately introduced, and thus the only water vapor that might be present was due to background water vapor introduced during previous chamber venting to the atmosphere.

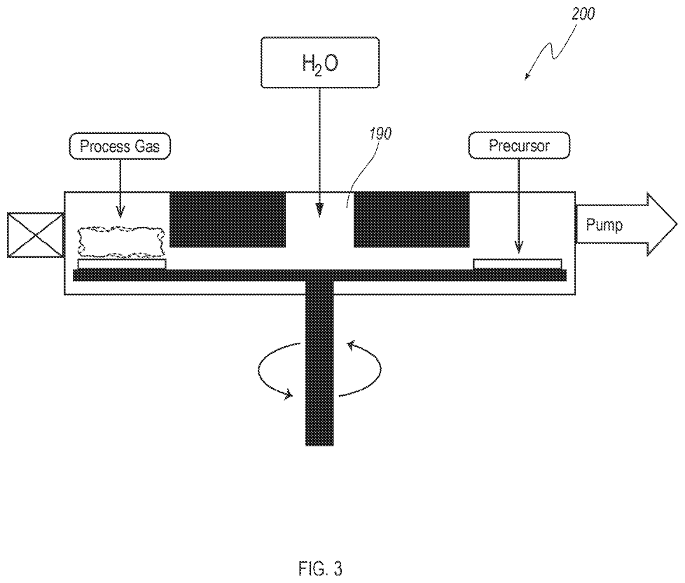

For the second two cases (cases 3 and 4), a vapor draw water source was plumbed into the center region 190 of the reactor 200, as illustrated in FIG. 3. The amount of water vapor introduced to the chamber was varied by using a needle valve in the delivery line (not shown).

In these experiments, SiO₂ films were deposited with various amounts of water present in the precursor region 180, as listed in Table 1.

TABLE 1

| | Reactor Drying | Water Introduced |
|---|---|---|
| | Time | from Water Source |
| Case 1 | 1.5 hours | 0 |
| Case 2 | 1 minute | 0 |
| Case 3 | >30 minutes | 1 mTorr |
| Case 4 | >30 minutes | 10 mTorr |

The reactor drying time is the time following pump down of the chamber 150 to operating pressure, prior to starting the deposition process. This might also be called a “bake out” time, used to allow background water present on internal surfaces to be desorbed and pumped away. The pressure of water deliberately introduced indicates the rise in total pressure when the water vapor was introduced, i.e., the partial pressure of water present during the deposition.

For all runs, other process variables were kept constant:
Substrate temperature 100° C.
Bis-diethylaminosilane (BDEAS) silicon precursor (a.k.a. SAM-24 from Air Liquide), vapor draw, heated to ˜55° C.
Oxygen process gas, 2 SLM flow rate, pressure ˜1.2 Torr
DC diode plasma, 1.5 amps current (˜450 V)
1000 laps (ALD cycles) at rotation speed of 150 RPM (2.5 cycles per second)

To compare relative ALD behavior and film quality, the growth rate per cycle, refractive index, and wet etch rate were compared and are listed in Table 2.

TABLE 2

| | | Refractive Index | |
|---|---|---|---|
| | ALD Growth Rate | at 633 nm | Wet Etch Rate |
| Case 1 | 0.11 nm/cycle | 1.45 | 51 nm/min |
| Case 2 | 0.11 nm/cycle | 1.45 | 53 nm/min |
| Case 3 | 0.11 nm/cycle | 1.45 | 51 nm/min |
| Case 4 | 0.12 nm/cycle | 1.45 | 51 nm/min |

The refractive index was determined by ellipsometry, using a Rudolph EL III ellipsometer. The wet etch rate was determined by etching the nominal 113-115 nm thick films for 1 minute in dilute hydrofluoric acid, 50:1 dilution in water (1% absolute HF concentration). The films were then re-measured on the ellipsometer to determine the amount of SiO₂ etched.

The ALD growth rate, refractive index, and wet etch rate for the films produced in each case indicate that ALD was occurring in cases 3 and 4, even though water was present during exposure to the amino-based silicon precursor. Additionally, the data indicates that the quality of the films produced in cases 3 and 4 was equivalent to the quality of the films produced in cases 1 and 2. Refractive index and wet etch rate are indirect measures of film quality. Refractive index and wet etch rate are relative indicators of film density. If CVD was occurring in cases 3 and 4, then the density of the films produced would likely have decreased, resulting in a reduction in film quality. If the density of the films had decreased, then the refractive index would likely be less and the wet etch rate likely higher than that observed for the films produced in cases 1 and 2. For cases 3 and 4, since the refractive index and wet etch rate for the films did not differ from that observed for the films produced in cases 1 and 2, this indicates that the density of the films produced in all four cases was similar. Therefore, this indicates that the quality of the films produced in all four cases was similar.

It will be apparent to those having skill in the art that many changes may be made to the details of the above-described embodiments and examples without departing from the underlying principles of the invention.

1. A water-insensitive method of forming a metal oxide on a substrate, the method comprising:
introducing a substrate into an atomic layer deposition (ALD) reactor;
exposing the substrate, while in the ALD reactor, to a gaseous amino-based metal precursor in the presence of trimethylaluminum (TMA) detectable water, wherein the amino-based metal precursor does not include alkoxy groups directly bonded to the metal;
subsequently exposing the substrate to an oxidant and forming a metal oxide on the substrate; and
repeating the preceding steps to grow a metal oxide film on the substrate, wherein a growth rate of the metal oxide film indicates a lack of reaction between the amino-based metal precursor and the water.

2. The method of claim 1, wherein subsequently exposing the substrate to an oxidant comprises exposing the substrate to a plasma.

3. The method of claim 2, wherein the plasma comprises an oxygen-containing plasma.

4. The method of claim 1, wherein the substrate introduced into the ALD reactor comprises a substrate containing significant quantities of water, such as at least 0.001% by volume or at least 0.01% by volume of a bulk structure of the substrate, in components in or on the bulk structure of the substrate, or both.

5. The method of claim 4, wherein the TMA detectable water present during exposing the substrate to the gaseous amino-based metal precursor comprises water off-gassed from the substrate.

6. The method of claim 1, wherein the TMA detectable water present during exposing the substrate to the gaseous amino-based metal precursor comprises residual water present in the ALD reactor.

7. The method of claim 1, wherein the TMA detectable water present during exposing the substrate to the gaseous amino-based metal precursor comprises separately introduced water vapor.

8. The method of claim 1, wherein the TMA detectable water comprises water vapor with a partial pressure of at least 10⁻⁵ Torr or at least 10⁻³ Torr.

9. The method of claim 1, wherein the substrate comprises a temperature-sensitive substrate and further comprising maintaining the ALD reactor at a temperature of less than 300° C.

10. The method of claim 1, wherein the amino-based metal precursor does not include halo or haloalkyl groups directly bonded to the metal.

11. The method of claim 1, wherein the amino-based metal precursor does not include any alkoxy groups, halo groups, or haloalkyl groups.

12. The method of claim 1, wherein the amino-based metal precursor comprises an amino-based silicon precursor and wherein the metal oxide film comprises a silica film.

13. The method of claim 12, wherein the amino-based silicon precursor comprises at least one nitrogen atom directly bonded to a silicon atom.

14. The method of claim 13, wherein the silicon atom is further directly bonded to only atoms independently selected from other nitrogen atoms, other silicon atoms, or hydrogen atoms.

15. The method of claim 13, wherein the silicon atom is further directly bonded to only atoms independently selected from other nitrogen atoms or other silicon atoms.

16. The method of claim 13, wherein the amino-based silicon precursor is selected from bisdiethylaminosilane (BDEAS), ORTHRUS, trisdiethylaminosilane (TDMAS or 3DMAS), bistertbutylaminosilane (BTBAS), diisopropylaminosilane (DIPAS), bisdiisoproplyaminodislane (BDIPADS), trisilylamine (TSA), neopentasilane, N(SiH₃)₃, and tris(isopropylamino)silane (TIPAS).

17. The method of claim 13, wherein the amino-based silicon precursor is selected from bisdiethylaminosilane (BDEAS), ORTHRUS, trisdiethylaminosilane (TDMAS or 3DMAS), bistertbutylaminosilane (BTBAS), diisopropylaminosilane (DIPAS), and bisdiisoproplyaminodislane (BDIPADS).

18. The method of claim 1, further comprising, subsequent to growing the metal oxide film, depositing a moisture-sensitive film on the metal oxide film.

19. A method of forming a moisture-sensitive film on a moisture-laden substrate, the method comprising:
providing a moisture-laden substrate;
growing a metal oxide film on the moisture-laden substrate utilizing atomic layer deposition (ALD) with an amino-based metal precursor devoid of alkoxy groups directly bonded to the metal; and
depositing a moisture-sensitive film on the moisture-laden substrate.

20. A coated substrate comprising:
a moisture-laden substrate;
a metal oxide film grown on the moisture-laden substrate; and
a moisture-sensitive film deposited on the metal oxide film.
